(19) United States
(12) Patent Application Publication
(10) Pub. No.: US 2025/0311593 A1
(43) Pub. Date: Oct. 2, 2025

(54) ELECTRONIC APPARATUS

(71) Applicant: Japan Display Inc., Tokyo (JP)

(72) Inventor: Genki ASOZU, Tokyo (JP)

(21) Appl. No.: 19/088,533

(22) Filed: Mar. 24, 2025

(30) Foreign Application Priority Data
Mar. 26, 2024 (JP) 2024-049209

(51) Int. Cl. H10K 59/80; H10K 39/34

(52) U.S. Cl. CPC H10K 59/871; H10K 39/34

(57) ABSTRACT

According to an aspect, an electronic apparatus includes: a substrate; a plurality of insulating films stacked on the substrate; an organic semiconductor device provided on the insulating films in an active area of the substrate; and a sealing film that covers the organic semiconductor device. The substrate, the insulating films, and the sealing film are stacked in a peripheral area outside the active area in the order as listed. On an outer edge side of the substrate, side surfaces of the insulating layers are provided on the active area side of a side surface of the substrate. In an area between a side surface of the substrate and side surfaces of the insulating layers on the outer edge side of the substrate, the sealing film is in direct contact with an upper surface of the substrate.

### CROSS-REFERENCE TO RELATED APPLICATION

This application claims the benefit of priority from Japanese Patent Application No. 2024-049209 filed on Mar. 26, 2024, the entire contents of which are incorporated herein by reference.

### BACKGROUND

### 1. Technical Field

What is disclosed herein relates to an electronic apparatus.

### 2. Description of the Related Art

As electronic apparatuses using organic semiconductor devices, there have been known organic electroluminescent display devices that include light-emitting elements using an organic semiconductor material (for example, Japanese Patent Application Laid-open Publication No. 2020-060651 and Japanese Patent Application Laid-open Publication No. 2018-113104) and optical sensors that include photodiodes (organic photodiodes (OPDs)) using an organic semiconductor material as an active layer.

Such electronic apparatuses are required to reduce or prevent penetration of moisture into an active area provided with the organic semiconductor devices.

### SUMMARY

According to an aspect, an electronic apparatus includes: a substrate; a plurality of insulating films stacked on the substrate; an organic semiconductor device provided on the insulating films in an active area of the substrate; and a sealing film that covers the organic semiconductor device. The substrate, the insulating films, and the sealing film are stacked in a peripheral area outside the active area in the order as listed. On an outer edge side of the substrate, side surfaces of the insulating layers are provided on the active area side of a side surface of the substrate. In an area between a side surface of the substrate and side surfaces of the insulating layers on the outer edge side of the substrate, the sealing film is in direct contact with an upper surface of the substrate.

### BRIEF DESCRIPTION OF THE DRAWINGS

FIG. 1 is a plan view schematically illustrating a detection device according to a first embodiment;

FIG. 2 is a block diagram illustrating a configuration example of the detection device according to the first embodiment;

FIG. 3 is a circuit diagram illustrating the detection device according to the first embodiment;

FIG. 4 is a plan view schematically illustrating an arrangement relation between a plurality of photodiodes in an active area, and insulating films and a sealing film in a peripheral area;

FIG. 5 is a sectional view along V-V′ of FIG. 4;

FIG. 6 is a sectional view along VI-VI′ of FIG. 4;

FIG. 7 is a sectional view schematically illustrating a magnified view of an area A in FIG. 6;

FIG. 8 is an explanatory diagram for explaining a method for manufacturing the detection device according to the first embodiment;

FIG. 9 is a plan view schematically illustrating a detection device according to a second embodiment;

FIG. 10 is a sectional view along X-X′ of FIG. 9;

FIG. 11 is a sectional view schematically illustrating a detection device according to a third embodiment; and

FIG. 12 is a sectional view schematically illustrating a display device according to a fourth embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

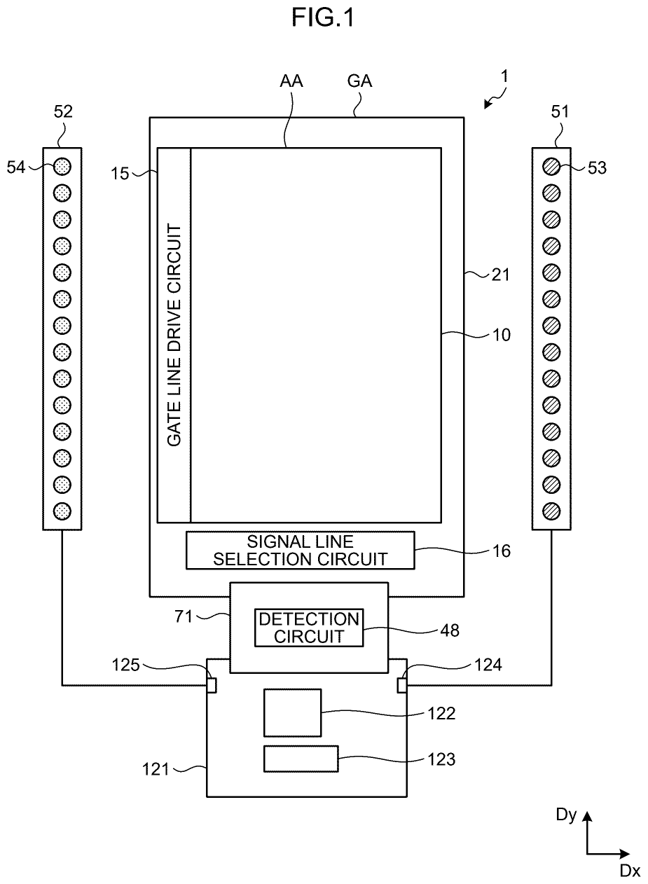

FIG. 1 is a plan view schematically illustrating a detection device according to a first embodiment. A detection device 1 according to the first embodiment corresponds to an example of an “electronic apparatus” of the present disclosure. A photodiode PD included in the detection device 1 corresponds to an example of an “organic semiconductor device” of the present disclosure.

As illustrated in FIG. 1, a detection device 1 includes a substrate 21, a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

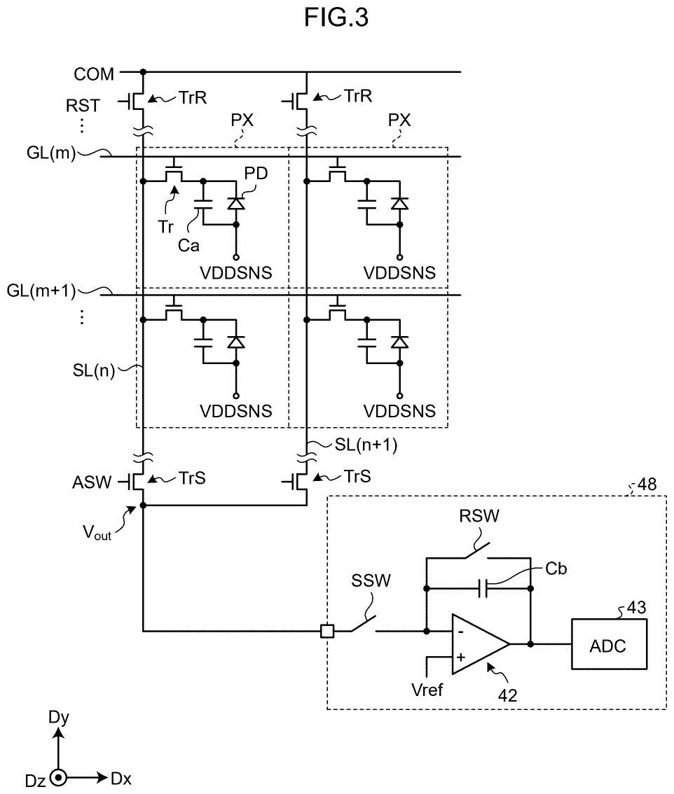

The substrate 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting or non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

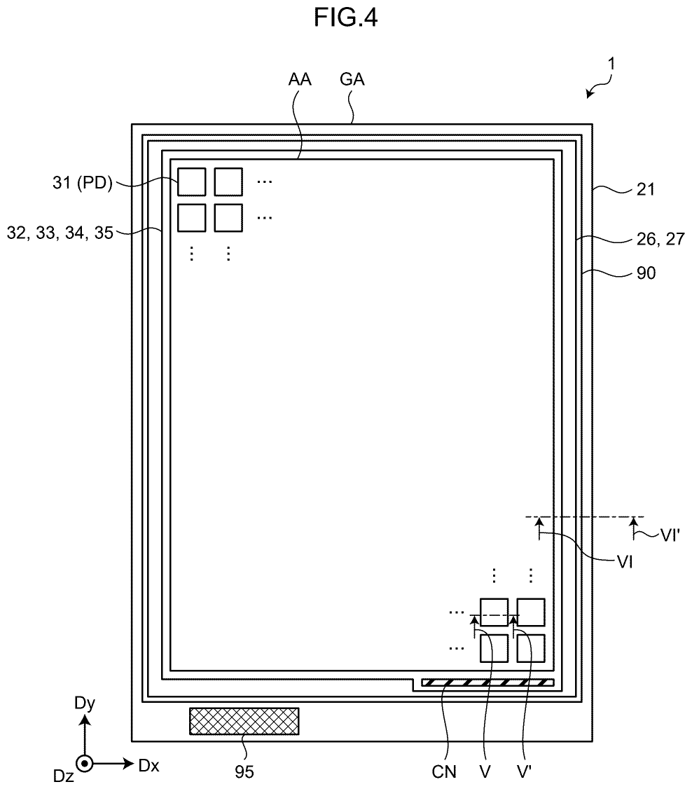

The substrate 21 has an active area AA and a peripheral area GA. The active area AA is an area provided with a plurality of the photodiodes PD (refer to FIG. 4) included in the sensor 10. The peripheral area GA is an area between the outer perimeter of the active area AA and the outer edges of the substrate 21, and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is a direction in a plane parallel to the substrate 21. The second direction Dy is a direction in the plane parallel to the substrate 21 and is a direction orthogonal to the first direction Dx. The second direction Dy may, however, non-orthogonally intersect the first direction Dx. A third direction Dz is a direction orthogonal to the first direction Dx and the second direction Dy and is a direction normal to a principal surface of the substrate 21. The term “plan view” refers to a positional relation when viewed in a direction orthogonal to the substrate 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect the fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

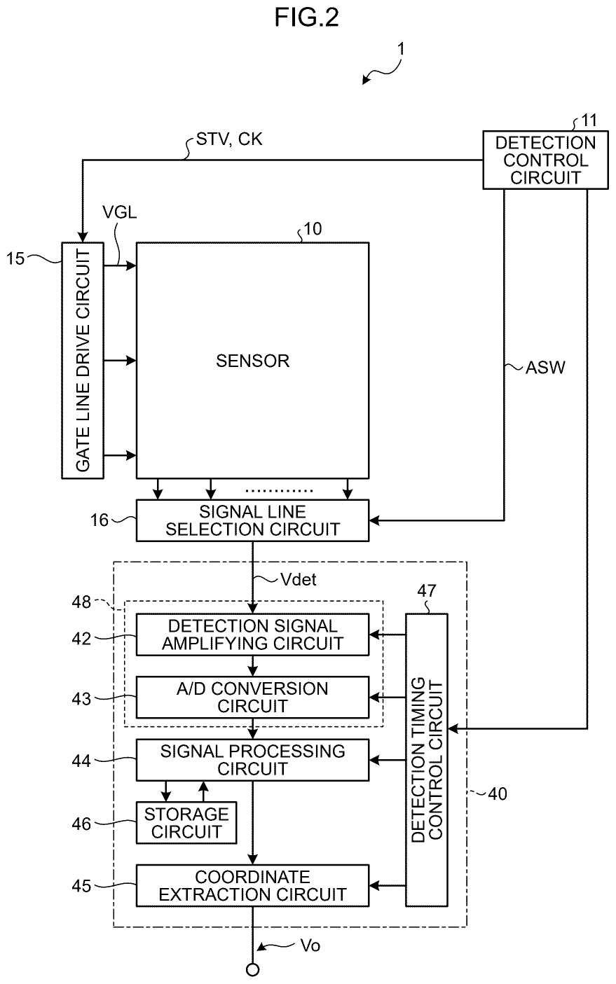

FIG. 2 is a block diagram illustrating a configuration example of the detection device according to the first embodiment. As illustrated in FIG. 2, the detection device 1 further includes a detection control circuit 11 and a detector 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light irradiating the photodiode PD as a detection signal Vdet to the signal line selection circuit 16. The sensor 10 performs the detection in response to a gate drive signal VGL supplied from the gate line drive circuit 15.

The detection control circuit 11 is a circuit that supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 is a circuit that drives a plurality of gate lines GL (refer to FIG. 3) based on the various control signals. The gate line drive circuit 15 sequentially or simultaneously selects the gate lines GL, and supplies the gate drive signals VGL to the selected gate lines GL. By this operation, the gate line drive circuit 15 selects the photodiodes PD coupled to the gate lines GL.

The signal line selection circuit 16 is a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signals Vdet of the photodiodes PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate these circuits synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signals Vdet. The A/D conversion circuit 43 converts analog signals output from the detection signal amplifying circuit 42 into digital signals.

The signal processing circuit 44 is a logic circuit that detects predetermined physical quantities received by the sensor 10 based on output signals of the detection circuit 48. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger or the like when the contact or proximity of the finger is detected by the signal processing circuit 44. The coordinate extraction circuit 45 is the logic circuit that also obtains detected coordinates of blood vessels in the finger or the palm. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the first embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL (m) and GL (m+1) arranged in the second direction Dy among the gate lines GL. FIG. 3 also illustrates two signal lines SL (n) and SL (n+1) arranged in the first direction Dx among the signal lines SL. The sensor pixel PX is an area surrounded by the gate lines GL and the signal lines SL.

The drive transistors Tr are provided correspondingly to the photodiodes PD. The drive transistor Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The others of the sources and the drains of the drive transistors Tr are each coupled to the cathode of the photodiode PD and the capacitive element Ca.

The anode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 via an output transistor TrS of the signal line selection circuit 16. Thus, the detection device 1 can detect a signal corresponding to the amount of the light applied to the photodiode PD for each sensor pixel PX.

During the readout period, a switch SSW is turned on to couple the detection circuit 48 to the signal line SL. The detection signal amplifying circuit 42 of the detection circuit 48 converts a current or an electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates the difference between the detection signal Vdet when light irradiates photodiode PD and the detection signal Vdet when light does not irradiate the photodiode PD, as each of the sensor output voltages Vo. The detection signal amplifying circuit 42 includes a capacitive element Cb and a reset switch RSW. In a reset period, the reset switch RSW is turned on to reset the electric charge of the capacitive element Cb.

The drive transistor Tr is not limited to the n-channel TFT and may be configured as a p-channel TFT. The pixel circuit of the sensor pixel PX illustrated in FIG. 3 is merely exemplary. The sensor pixel PX may be provided with a plurality of transistors corresponding to one photodiode PD.

The following describes a configuration of the photodiode PD and a sealing film 90 with reference to FIGS. 4 to 6. FIG. 4 is a plan view schematically illustrating an arrangement relation among the photodiodes in the active area, and insulating films and the sealing film in the peripheral area.

As illustrated in FIG. 4, the photodiodes PD (organic optical sensors) are arranged in a matrix having a row-column configuration in the active area AA. The photodiodes PD each include a lower electrode 31, a lower buffer layer 32, an active layer 33, an upper buffer layer 34, and an upper electrode 35. A plurality of the lower electrodes 31 are provided so as to be separated from each other and correspond to the photodiodes PD, and arranged in a matrix having a row-column configuration in the active area AA. The lower buffer layer 32, the active layer 33, the upper buffer layer 34, and the upper electrode 35 are continuously provided across the photodiodes PD and provided over the entire active area AA. A portion of the upper electrode 35 extends into the peripheral area GA, is coupled to a contact portion CN, and is electrically coupled to external circuitry (such as the control circuit 122 and the power supply circuit 123 (refer to FIG. 1)) through wiring of the substrate 21.

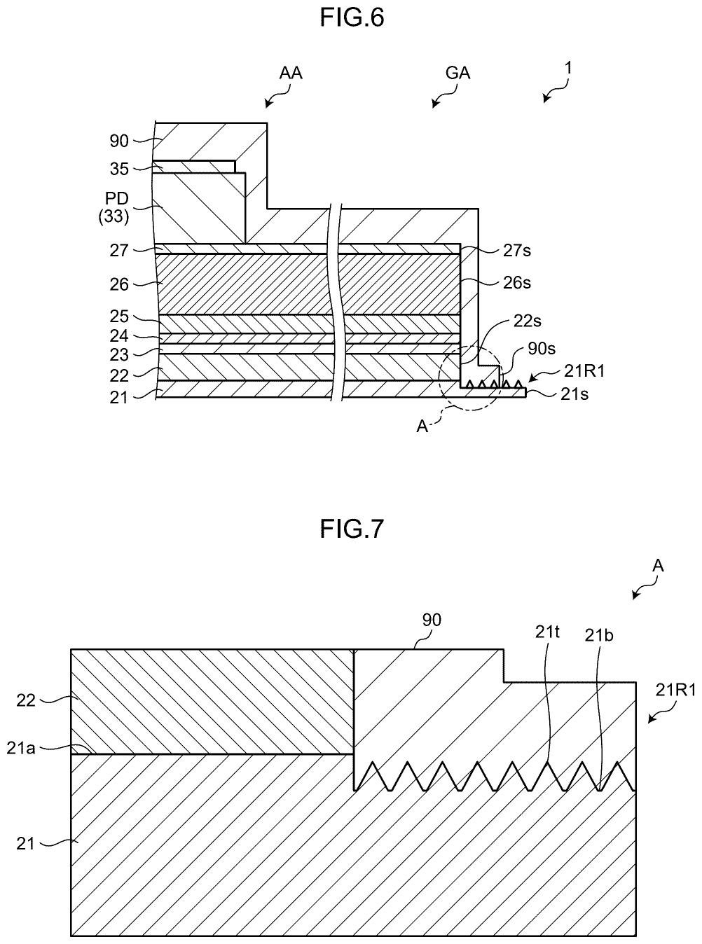

The detection device 1 includes the sealing film 90 covering the photodiodes PD. The sealing film 90 is provided over the active area AA and the peripheral area GA and provided to outer edge sides of the substrate 21. The sealing film 90 extends to further outer edge sides of the substrate 21 than a plurality of insulating films (for example, an organic insulating film 26, a barrier film 27, and the like) provided on the substrate 21. The sealing film 90 can reduce moisture entering the active area AA from the outer edge sides of the substrate 21. A detailed configuration of the substrate 21, the insulating films, and the sealing film 90 will be described later with reference to FIGS. 6 and 7.

A mounting portion 95 is provided on the substrate 21, outside the outer perimeter of the sealing film 90. The mounting portion 95 includes, for example, a coupling terminal for coupling to the wiring substrate 71 (refer to FIG. 1). Alternatively, the mounting portion 95 may include mounting terminals for mounting integrated circuits (ICs) included in the detection circuit 48 and the like.

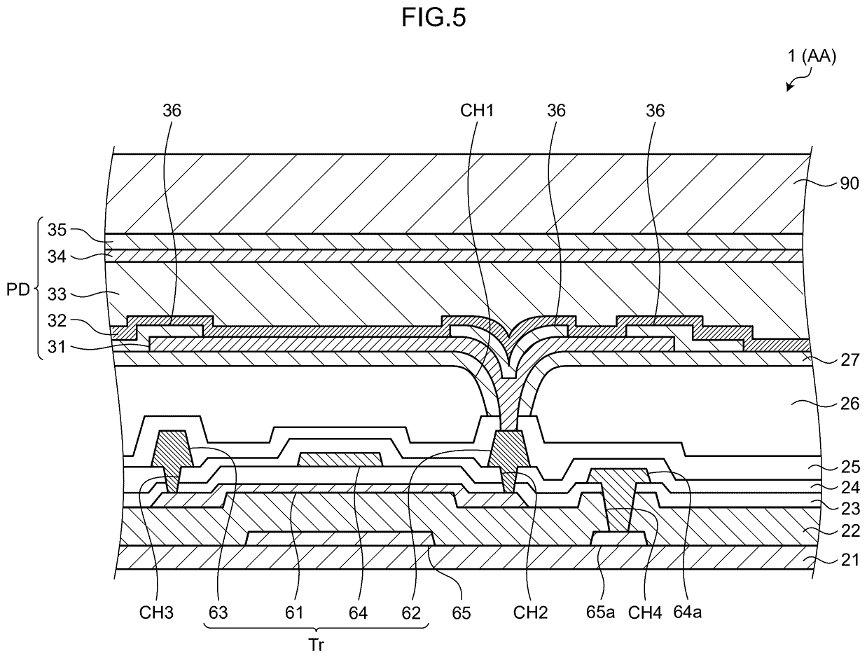

The following describes a multilayered structure of the photodiodes PD and the sealing film 90 of the detection device 1. FIG. 5 is a sectional view along V-V′ of FIG. 4.

In the following description, a direction from the substrate 21 toward the sealing film 90 in a direction orthogonal to a surface of the substrate 21 is referred to as “upper side” or simply “above”. A direction from the sealing film 90 toward the substrate 21 is referred to as “lower side” or simply “below”.

As illustrated in FIG. 5, the detection device 1 includes the substrate 21, the drive transistor Tr, a plurality of inorganic insulating films (undercoat film 22, gate insulating film 23, interlayer insulating film 24, and overlay insulating film 25), the organic insulating film 26, the barrier film 27, the photodiode PD, and the sealing film 90. In the active area AA, the inorganic insulating films (undercoat film 22, gate insulating film 23, interlayer insulating film 24, and overlay insulating film 25), the organic insulating film 26, the barrier film 27, the photodiode PD, and the sealing film 90 are stacked in this order on the substrate 21.

The substrate 21 is an insulating substrate formed of a film-like resin. The drive transistor Tr is provided in an area overlapping the lower electrode 31 of the photodiode PD. Specifically, the drive transistor Tr includes a semiconductor layer 61, a source electrode 62, a drain electrode 63, and a gate electrode 64.

A light-blocking film 65 is provided on the substrate 21. The light-blocking film 65 is provided between the semiconductor layer 61 and the substrate 21. The light-blocking film 65 reduces light entering a channel region of the semiconductor layer 61 from the substrate 21 side.

The undercoat film 22 is provided on the substrate 21 so as to cover the light-blocking film 65. The undercoat film 22 is formed, for example, of an inorganic insulating film such as a silicon nitride film or a silicon oxide film. The configuration of the undercoat film 22 is not limited to that illustrated in FIG. 5. For example, the undercoat film 22 may be a multilayered film having two, three, or more layers.

The drive transistor Tr is provided above the substrate 21. The semiconductor layer 61 is provided on the undercoat film 22. The gate insulating film 23 is provided on the undercoat film 22 so as to cover the semiconductor layer 61. The gate insulating film 23 is, for example, an inorganic insulating film such as a silicon oxide film. The gate electrode 64 is provided on the gate insulating film 23.

In the example illustrated in FIG. 5, the drive transistor Tr has a top-gate structure. However, the drive transistor Tr is not limited thereto and may have a bottom-gate structure or a dual-gate structure in which the gate electrodes 64 are provided on the upper and lower sides of the semiconductor layer 61.

The interlayer insulating film 24 is provided on the gate insulating film 23 so as to cover the gate electrode 64. The interlayer insulating film 24 has, for example, a multilayered structure of a silicon nitride film and a silicon oxide film. The source electrode 62 and the drain electrode 63 are provided on the interlayer insulating film 24. The source electrode 62 is coupled to a source region of the semiconductor layer 61 through a contact hole CH2 provided through the gate insulating film 23 and the interlayer insulating film 24. The drain electrode 63 is coupled to a drain region of the semiconductor layer 61 through a contact hole CH3 provided through the gate insulating film 23 and the interlayer insulating film 24. The overlay insulating film 25 is provided on the interlayer insulating film 24 so as to cover the source electrode 62 and the drain electrode 63.

Coupling wiring 64a is provided in the same layer as the gate electrode 64. The coupling wiring 64a is electrically coupled to the gate electrode 64. Coupling wiring 65a is provided in the same layer as the light-blocking film 65. The coupling wiring 65a is electrically coupled to the light-blocking film 65. The coupling wiring 64a is coupled to the coupling wiring 65a through a contact hole CH4 penetrating the undercoat film 22 and the gate insulating film 23. As a result, the light-blocking film 65 is electrically coupled to the gate electrode 64 via the coupling wiring 64a and 65a and is supplied with the same potential as that of the gate electrode 64.

The organic insulating film 26 is provided on the overlay insulating film 25 so as to cover the source electrode 62 and the drain electrode 63 of the drive transistor Tr. The organic insulating film 26 is a planarizing film formed of an organic insulating material. In the present embodiment, a contact hole CH1 in the organic insulating film 26 is provided in an area thereof overlapping the source electrode 62. The lower electrode 31 of the photodiode PD is electrically coupled to the source electrode 62 at the bottom of the contact hole CH1.

The detection device 1 may have a configuration in which the overlay insulating film 25 among the inorganic insulating films (undercoat film 22, gate insulating film 23, interlayer insulating film 24, and overlay insulating film 25) is not provided. In that case, the organic insulating film 26 is provided on the interlayer insulating film 24 so as to cover the source electrode 62 and the drain electrode 63.

The barrier film 27 is provided on the organic insulating film 26. The barrier film 27 is formed, for example, of an inorganic insulating material such as a silicon nitride film (SiN).

The photodiode PD is provided on the barrier film 27. In the photodiode PD, the lower electrode 31, the lower buffer layer 32, the active layer 33, the upper buffer layer 34, and the upper electrode 35 are stacked in this order in the direction orthogonal to the substrate 21. The photodiode PD of the present embodiment is an organic photodiode (OPD) using an organic semiconductor as the active layer 33.

The lower electrode 31 is formed, for example, of a light-transmitting conductive material such as indium tin oxide (ITO). The lower buffer layer 32, the active layer 33, the upper buffer layer 34, and the upper electrode 35 are provided continuously across the photodiodes PD. Specifically, the lower buffer layer 32, the active layer 33, the upper buffer layer 34, and the upper electrode 35 are provided so as to overlap the lower electrodes 31 and the barrier film 27 provided between the adjacent lower electrodes 31.

An insulating film 36 is provided so as to cover the peripheries of the lower electrode 31. The insulating film 36 is provided so as to cover the contact hole CH1, and covers the lower electrode 31 in an area overlapping the contact hole CH1. The insulating film 36 insulates between the lower electrodes 31 of the adjacent photodiodes PD. Even if a step break occurs in the lower buffer layer 32 in the area overlapping the contact hole CH1, the occurrence of a short circuit between the active layer 33 and the lower electrode 31 can be prevented or reduced because the insulating film 36 is provided. In the present embodiment, the insulating film 36 is formed of an inorganic insulating material, such as a silicon nitride (SiN) film or a silicon oxide (SiO₂) film.

The active layer 33 changes in characteristics (for example, voltage-current characteristics and resistance value) according to light emitted thereto. An organic material is used as a material of the active layer 33. Specifically, the active layer 33 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 33, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 33 can be formed by a vapor deposition process (dry process) using any of the low-molecular-weight organic materials listed above. In this case, the active layer 33 may be, for example, a multilayered film of CuPc and F₁₆CuPc, or a multilayered film of rubrene and C₆₀. The active layer 33 can also be formed by a coating process (wet process). In this case, the active layer 33 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 33 can be a film made of a mixture of P3HT and PCBM, or a film made of a mixture of F8BT and PDI. The active layer 33 is not limited to the bulk heterostructure and may have a positive-intrinsic-negative (PIN) structure.

The lower buffer layer 32 and the upper buffer layer 34 are provided to facilitate holes and electrons generated in the active layer 33 to reach the lower electrode 31 or the upper electrode 35. The lower buffer layer 32 is provided between the lower electrode 31 and the active layer 33 and is in direct contact with the lower electrode 31 and the active layer 33. The lower buffer layer 32 is provided between the adjacent lower electrodes 31 so as to cover the barrier film 27.

The upper buffer layer 34 is provided between the active layer 33 and the upper electrode 35 and is in direct contact with the active layer 33 and the upper electrode 35. The upper electrode 35 is provided on the upper buffer layer 34. The upper electrode 35 is formed, for example, of a light-transmitting conductive material such as ITO or indium zinc oxide (IZO). The upper electrode 35 is not limited thereto and may be formed of, for example, a non-light-transmitting conductive material such as silver (Ag).

In the present embodiment, the lower electrode 31 is a cathode electrode of the photodiode PD, and the upper electrode 35 is an anode electrode of the photodiode PD. In this case, the lower buffer layer 32 is an electron transport layer and the upper buffer layer 34 is a hole transport layer. Polyethylenimine ethoxylated (PEIE) is used as a material of the electron transport layer. The material of the hole transport layer is a metal oxide layer. Tungsten oxide (WO₃), molybdenum oxide, or the like is used as the metal oxide layer.

The lower electrode 31 may be the anode electrode of the photodiode PD, and the upper electrode 35 may be the cathode electrode of the photodiode PD. In that case, the lower buffer layer 32 may be a hole transport layer, and the upper buffer layer 34 may be an electron transport layer.

The sealing film 90 is provided on the upper electrode 35. The sealing film 90 is formed, for example, of an inorganic insulating material such as a silicon nitride (SiN) film. The sealing film 90 well seals the photodiode PD and thus can reduce moisture entering the photodiode PD from the upper surface side thereof. The sealing film 90 is not limited to a single-layer film and may be a multilayered film. The sealing film 90 may have multiple layers including one or more inorganic sealing films formed of an inorganic insulating material and one or more organic sealing films formed of an organic insulating material.

The following describes a configuration of the sealing film 90 and the insulating films in the peripheral area GA. FIG. 6 is a sectional view along VI-VI′ of FIG. 4. FIG. 7 is a sectional view schematically illustrating a magnified view of an area A in FIG. 6. To facilitate understanding, FIG. 6 illustrates the multilayer configuration of the inorganic insulating films, the organic insulating film 26, the barrier film 27, the photodiode PD, and the sealing film 90 in the active area AA as well as the configuration of the peripheral area GA. The configuration of the active area AA in FIG. 6 is the same as that described with reference to FIG. 5 and will not be described again.

As illustrated in FIG. 6, the undercoat film 22, the gate insulating film 23, the interlayer insulating film 24, the overlay insulating film 25, the organic insulating film 26, the barrier film 27, and the sealing film 90 are provided across the active area AA and the peripheral area GA. In the following description, the undercoat film 22, the gate insulating film 23, the interlayer insulating film 24, the overlay insulating film 25, the organic insulating film 26, and the barrier film 27 will each be simply referred to as an “insulating film” or will be simply referred to as “insulating films” collectively when they need not be distinguished from one another.

In the active area AA, the insulating films (undercoat film 22 to barrier film 27), the photodiode PD (organic semiconductor device), and the sealing film 90 are stacked in this order. In the peripheral area GA outside the active area AA, the insulating films (undercoat film 22 to barrier film 27) and the sealing film 90 are stacked in this order.

In the present embodiment, on an outer edge side of the substrate 21, side surfaces of the insulating films (from a side surface 22s of the undercoat film 22 to a side surface 26s of the organic insulating film 26 and a side surface 27s of the barrier film 27) are positioned inside a side surface 21s of the substrate 21 (i.e., on the active area AA side of the side surface 21s of the substrate 21). That is, the outer edge side of the substrate 21 has an area where the insulating films (undercoat film 22 to barrier film 27) are not provided on the substrate 21.

On the outer edge side of the substrate 21, a first uneven portion 21R1 is provided on the upper surface of the substrate 21 in an area between the side surface 21s of the substrate 21 and the side surfaces of the insulating films. As illustrated in FIG. 7, the first uneven portion 21R1 has a plurality of asperities. The first uneven portion 21R1 of the substrate 21 has larger surface roughness than an upper surface 21a of the substrate 21 in an area thereof overlapping the insulating films.

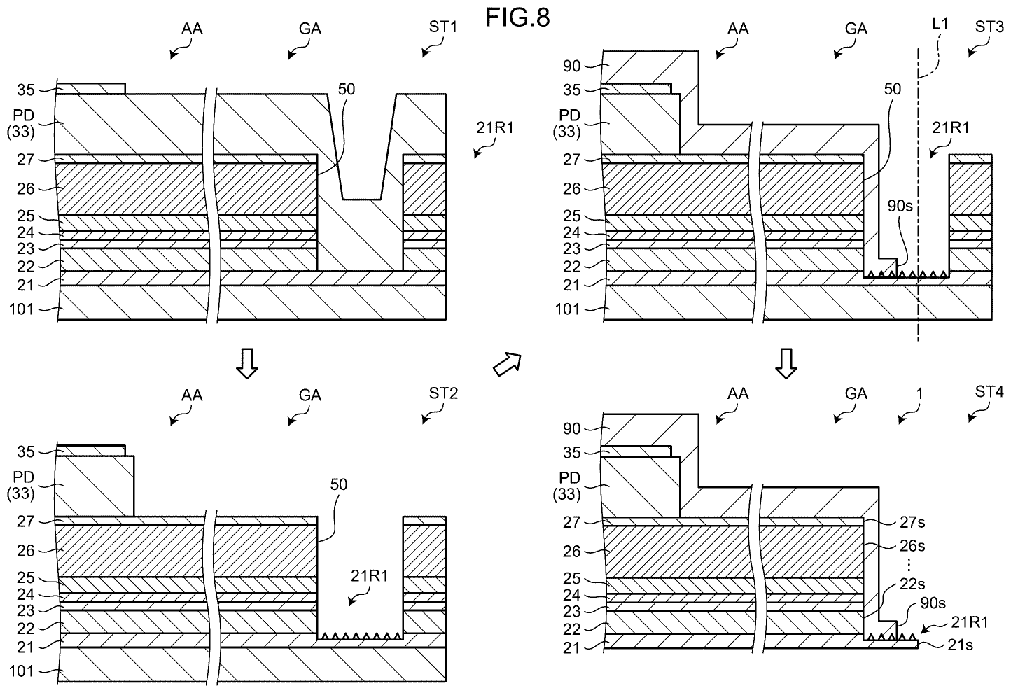

As illustrated in FIG. 7, the height position of bottoms 21b of the asperities of the first uneven portion 21R1 is lower than the height position of the upper surface 21a of the substrate 21 in the area thereof overlapping the insulating films. The height position of tops 21t of the asperities of the first uneven portion 21R1 is equal to or lower than the height position of the upper surface 21a of the substrate 21 in the area thereof overlapping the insulating films. This is because the first uneven portion 21R1 of the substrate 21 is formed by etching such as reactive ion etching (RIE). A process to form the first uneven portion 21R1 of the substrate 21 will be described later with reference to FIG. 8.

The sealing film 90 covers the photodiode PD in the active area AA and also covers the upper surface and the side surfaces of the insulating films (from the side surface 22s of the undercoat film 22 to the side surface 26s of the organic insulating film 26 and the side surface 27s of the barrier film 27) in the peripheral area GA. The sealing film 90 is in direct contact with the upper surface of the substrate 21 in the area thereof between the side surface 21s of the substrate 21 and the side surfaces of the insulating films. That is, on the outer edge side of the substrate 21, the sealing film 90 covers the first uneven portion 21R1.

A side surface 90s of the sealing film 90 is positioned inside the side surface 21s of the substrate 21 (i.e., on the active area AA side of the side surface 21s of the substrate 21). That is, on the outer edge side of the substrate 21, the first uneven portion 21R1 of the substrate 21 has an area provided with the sealing film 90 and an area not provided with the sealing film 90.

Thus, in the peripheral area GA, the side surfaces of the insulating films (from the side surface 22s of the undercoat film 22 to the side surface 26s of the organic insulating film 26 and the side surface 27s of the barrier film 27) are positioned on the active area AA side of the side surface 21s of the substrate 21. The sealing film 90 covers the side surfaces of the insulating films and is provided in contact with the first uneven portion 21R1 formed on the upper surface of the substrate 21, on the outer edge side of the substrate 21. This configuration makes a contact area between the substrate 21 and the sealing film 90 larger than a contact area when the first uneven portion 21R1 is not provided, and thus can ensure adhesion between the substrate 21 and the sealing film 90 on the outer edge side of the substrate 21. The substrate 21 is formed of an organic material such as polyimide and the sealing film 90 is formed of an inorganic material such as a silicon nitride (SiN) film, as described above. Even if the substrate 21 and the sealing film 90 are formed of different materials, the adhesion between the substrate 21 and the sealing film 90 can be ensured because the substrate 21 has the first uneven portion 21R1. Such a configuration seals ends of interfaces between the substrate 21 and the insulating films (undercoat film 22 to organic insulating film 26 and barrier film 27) with the sealing film 90, and thus reduces moisture entering from the outer edge side of the substrate 21.

To clarify the description, the asperities of the first uneven portion 21R1 illustrated in FIGS. 6 and 7 are exaggerated and differ from the actual surface state. For example, the asperities of the first uneven portion 21R1 are not limited to a triangular shape and may have portions curved in an arc shape. The first uneven portion 21R1 is not limited to a case where regular asperities are repeatedly formed, and the asperities may be irregularly formed. The side surfaces of the insulating films (from the side surface 22s of the undercoat film 22 to the side surface 26s of the organic insulating film 26 and the side surface 27s of the barrier film 27) are provided orthogonally to the upper surface of the substrate 21, but are not limited to this configuration, and may be provided in a tapered manner.

The following describes a method for manufacturing the detection device 1. FIG. 8 is an explanatory diagram for explaining the method for manufacturing the detection device according to the first embodiment. As illustrated in FIG. 8, in the detection device 1 before an outer shape thereof is cut, the substrate 21 is attached onto a support substrate 101 made of glass or the like. The detection device 1 of the present embodiment is formed by cutting, along an outer shape cut line L1 (refer to Step ST3), the detection device 1 before the outer shape thereof is cut.

The insulating films (undercoat film 22 to organic insulating film 26 and barrier film 27), the drive transistor Tr (not illustrated in FIG. 8), and various types of wiring are formed on the substrate 21. A groove 50 is provided at an area overlapping the outer shape cut line L1 on the outer edge side of the substrate 21. The groove 50 is formed by removing portions of the insulating films by etching or the like. Then, the photodiode PD is formed on the barrier film 27. The active layer 33 of the photodiode PD is formed by being applied onto the entire surface of each of the active area AA and the peripheral area GA so as to cover the upper surface of the insulating films (upper surface of barrier film 27) and the groove 50 (Step ST1). An area of the active layer 33 that overlaps the active area AA is provided with the upper electrode 35.

Then, the active layer 33 is patterned, using the upper electrode 35 of the photodiode PD as a mask. That is, the active layer 33 in the peripheral area GA (area not overlapping upper electrode 35) is removed by etching such as the RIE (Step ST2). The active layer 33 overlapping the upper electrode 35 is not etched and is formed as the photodiode PD. At this time, the active layer 33 provided in the groove 50 is also removed by the RIE or the like, and further, a surface of the substrate 21 exposed at the bottom of the groove 50 is also processed by the RIE. Thus, the first uneven portion 21R1 having the asperities on the upper surface of the substrate 21 is formed in an area overlapping the groove 50.

Then, the sealing film 90 is formed so as to cover the photodiode PD (Step ST3). The sealing film 90 is formed across the area from the active area AA to the peripheral area GA and also formed in the groove 50. As a result, the sealing film 90 is in direct contact with the upper surface of the substrate 21 (first uneven portion 21R1) at the bottom of the groove 50. The sealing film 90 is patterned such that the side surface 90s is located on the inner side (on the active area AA side) of the outer shape cut line L1.

Then, the substrate 21 is cut along the outer shape cut line L1 in the area overlapping the bottom of the groove 50, for example, by a laser process (Step ST4). The substrate 21 is then separated from the support substrate 101, and the detection device 1 is formed. The outer-shape cutting of the substrate 21 is not limited to the laser process. The cutting process may be performed, for example, by die cutting.

The process described above forms the first uneven portion 21R1 on the outer edge side of the substrate 21 and can improve the adhesion between the first uneven portion 21R1 of the substrate 21 and the sealing film 90. Therefore, the detection device 1 reduces moisture entering from the outer edge side of the substrate 21.

### Second Embodiment

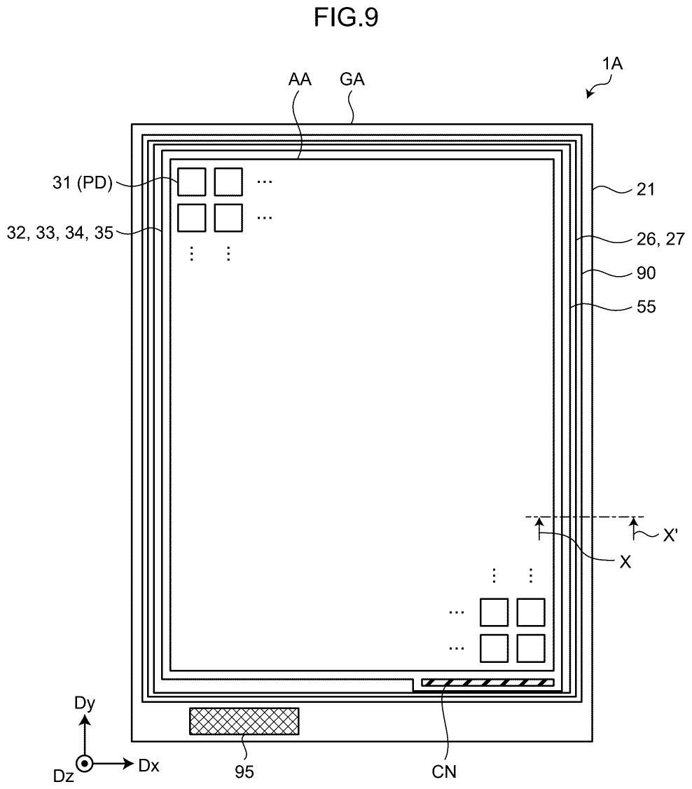

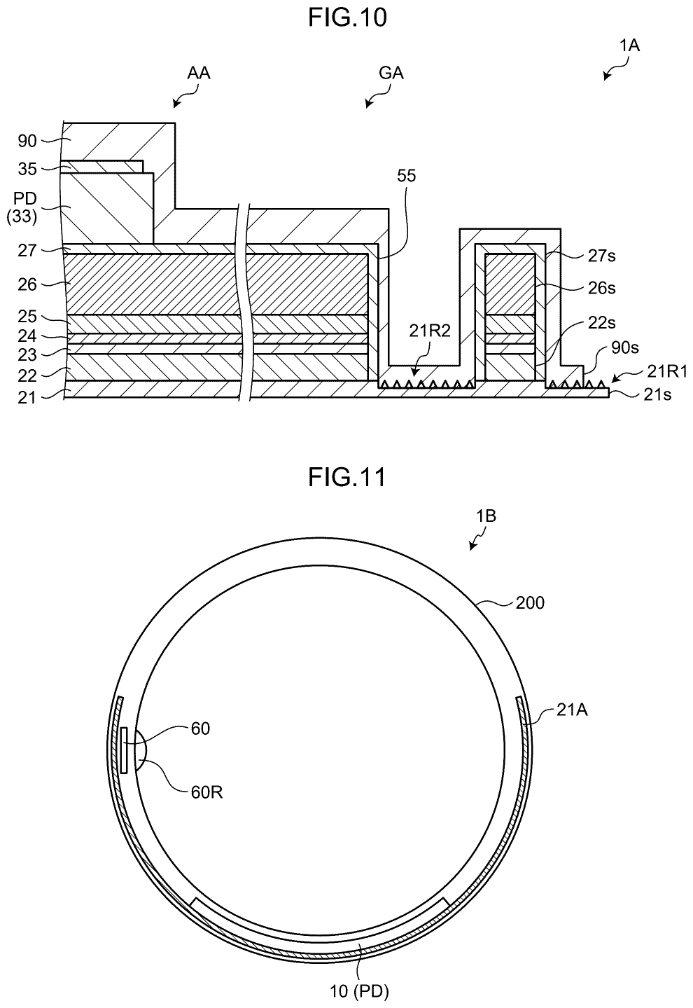

FIG. 9 is a plan view schematically illustrating a detection device according to a second embodiment. FIG. 10 is a sectional view along X-X′ of FIG. 9. In the following description, the same components as those described in the embodiment described above are denoted by the same reference numerals, and the description thereof will not be repeated.

As illustrated in FIGS. 9 and 10, a detection device 1A of the second embodiment has a groove 55 provided in the insulating films (undercoat film 22 to organic insulating film 26 and barrier film 27) in the peripheral region GA. The sealing film 90 is provided so as to cover the groove 55.

The groove 55 extends along the outer edge of the substrate 21 in plan view and is provided so as to surround the outer perimeter of the active area AA. In the example illustrated in FIG. 9, the groove 55 has a continuous frame shape. However, FIG. 9 is merely schematically illustrated, and the groove 55 may be unprovided in a partial area along the outer perimeter of the active area AA.

As illustrated in FIG. 10, the groove 55 is provided so as to penetrate the insulating films (undercoat film 22 to organic insulating film 26) in the thickness direction thereof. The barrier film 27 is provided so as to cover the side surfaces of the insulating films (from the side surface of the undercoat film 22 to the side surface of the organic insulating film 26) in the groove 55. In other words, the side surface of the groove 55 is formed with the barrier film 27. The barrier film 27 is not provided at the bottom of the groove 55, and a second uneven portion 21R2 having a plurality of asperities is provided on the upper surface of the substrate 21 at the bottom of the groove 55.

The sealing film 90 extends to the outer edge side of the substrate 21 so as to cover the photodiode PD in the active area AA and cover the groove 55 in the peripheral area GA. The sealing film 90 is in direct contact with the upper surface of the substrate 21 at the bottom of the groove 55. The sealing film 90 is further in direct contact with the upper surface of the substrate 21 in an area thereof between the side surface 21s of the substrate 21 and the side surface 27s of the barrier film 27, on the outer edge side of the substrate 21. That is, the sealing film 90 covers the second uneven portion 21R2 of the substrate 21 at the bottom of the groove 55 and covers the first uneven portion 21R1 on the outer edge side of the substrate 21.

This configuration of the detection device 1A of the second embodiment makes the contact area between the substrate 21 and the sealing film 90 larger than in the first embodiment described above, and therefore, can improve the adhesion between the substrate 21 and the sealing film 90.

In the present embodiment, the groove 55 is provided in the insulating films. With this configuration, the length along interfaces of surfaces of the insulating films with the sealing film 90 is longer the length than when the groove 55 is not provided. The length along the interfaces of the surfaces of the insulating films with the sealing film 90 is, specifically, the total length along the upper surface of the barrier film 27, the side surface of the groove 55 (side surface of barrier film 27), and the bottom of the groove 55. This configuration lengthens the penetration path of moisture from the outer edge side of the substrate 21 to the active area AA, and therefore, can reduce moisture entering the active area AA. The barrier film 27 covers the side surfaces of the insulating films (from the side surface of the undercoat film 22 to the side surface of the organic insulating film 26) in the groove 55 and on the outer edge side of the substrate 21. This configuration covers the ends of the interfaces between the insulating films with the barrier film 27 and the sealing film 90, and therefore, well reduces moisture entering from the outer edge side of the substrate 21.

The groove 55 is not limited to one. A plurality of the grooves 55 may be provided adjacent to one another from the outer edge side of the substrate 21 toward the active area AA. The configuration in which the barrier film 27 covers the side surfaces of the insulating films (from the side surface of the undercoat film 22 to the side surface of the organic insulating film 26) can be applied to the detection device 1 of the first embodiment.

### Third Embodiment

FIG. 11 is a sectional view schematically illustrating a detection device according to a third embodiment. A detection device 1B illustrated in FIG. 11 is a finger ring-shaped device that can be worn on and removed from a human body and worn on the object to be detected of the human body. The object to be detected is a finger and may be any one of a thumb, an index finger, a middle finger, a ring finger, and a little finger. The detection device 1B can detect biometric information on a living body from the object to be detected (finger) wearing the detection device 1B.

As illustrated in FIG. 11, the detection device 1B includes at least a housing 200, and at least a light source 60 and the sensor 10 (photodiode PD) that are provided on a flexible substrate 21A. The housing 200 accommodates therein the light source 60 and the sensor 10 (photodiode PD). FIG. 11 does not illustrate components other than the housing 200, the flexible substrate 21A, the light source 60, a light emitter 60R, and the sensor 10 (photodiode PD).

The housing 200 is formed in a ring shape (annular shape) that can be worn on the object to be detected (finger), and is a wearable member to be worn on the living body. The housing 200 is formed of a housing material such as a synthetic resin. External surfaces of the housing 200 are made of a light-blocking resin. This configuration reduces noise caused by external light. An internal surface of the housing 200 is made of a light-transmitting resin. With this configuration, light emitted by the light source 60 is applied to the object to be detected (finger), and the sensor 10 (photodiode PD) can receives light from the object to be detected (finger).

The detection device 1B according to the third embodiment can be combined with the detection device 1 of the first embodiment or the detection device 1A of the second embodiment described above. The detection devices 1 and 1A described above are not limited to the finger ring-shaped device and can be applied to other various devices.

### Fourth Embodiment

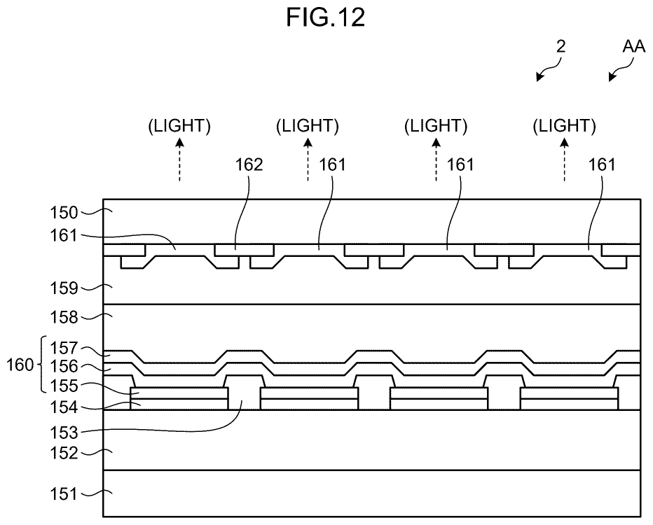

FIG. 12 is a sectional view schematically illustrating a display device according to a fourth embodiment. A display device 2 according to the fourth embodiment corresponds to an example of the “electronic apparatus” of the present disclosure. An organic light-emitting element 160 included in the display device 2 corresponds to an example of the “organic semiconductor device” of the present disclosure.

The display device 2 according to the fourth embodiment includes a self-luminous OLED panel. The following describes a specific configuration example of the OLED panel with reference to FIG. 12.

As illustrated in FIG. 12, the display device 2 includes a substrate 151, insulating layers 152 and 153, a reflective layer 154, an organic light-emitting element 160 (lower electrode 155, self-luminous layer 156, and upper electrode 157), insulating layers 158 and 159, a color filter 161 as a color conversion layer, a black matrix 162 as a light-blocking layer, and a substrate 150.

The substrate 151 is, for example, a semiconductor substrate of silicon or the like, a glass substrate, or a resin substrate. A lighting drive circuit or the like is formed or held on the substrate 151. The insulating layer 152 is a protective film that protects the lighting drive circuit or the like mentioned above and can be made using silicon oxide, silicon nitride, or the like.

The organic light-emitting element 160 is formed by stacking the lower electrode 155, the self-luminous layer 156, and the upper electrode 157 in this order in the active area AA of the substrate 151. The lower electrode 155 included in the organic light-emitting element 160 is a conductor that serves as the anode (positive pole) of an OLED. The upper electrode 155 is formed of a light-transmitting conductive material such as ITO. The self-luminous layer 156 contains organic materials and includes a hole injection layer, a hole transport layer, a light-emitting layer, an electron transport layer, and an electron injection layer, which are not illustrated. The upper electrode 157 is formed of a light-transmitting conductive material such as ITO. In the present embodiment, ITO is exemplified as the light-transmitting conductive material, but the light-transmitting conductive material is not limited to ITO. A conductive material having another composition such as indium zinc oxide (IZO) may be used as the light-transmitting conductive material. The upper electrode 157 is the cathode (negative pole) of the OLED.

The insulating layer 153 is an insulating layer that is called “bank” and partitions the pixels. The reflective layer 154 is formed of a material with a metallic luster, such as silver, aluminum, or gold that reflects light coming from the self-luminous layer 156.

The insulating layer 158 is a sealing layer that seals the upper electrode 157 and can be made using silicon oxide, silicon nitride, or the like. The insulating layer 159 is a planarizing layer that planarizes asperities formed by the bank and can be made using silicon oxide, silicon nitride, or the like. The substrate 150 is a light-transmitting substrate that protects the entire display device 2 and can be made using a glass substrate, for example.

FIG. 12 illustrates an example in which the lower electrode 155 is the anode (positive pole) and the upper electrode 157 is the cathode (negative pole), but the lower and the upper electrodes 155 and 157 are not limited to this example. The lower electrode 155 may be the cathode and the upper electrode 157 may be the anode. The stacking order of the carrier injection layers (hole injection layer and electron injection layer), the carrier transport layers (hole transport layer and electron transport layer), and the light-emitting layer can be changed as appropriate.

Although FIG. 12 illustrates the configuration in which the color filter 161 is used to determine the color of each of the pixels, color display may be performed by varying the color of the light emitted by the OLED provided in each of the pixels. The color display function is not essential. In the case of monochromatic display, the color filter 161 can be omitted.

In the present embodiment also, the sealing structure is formed on the outer edge side of the substrate 151, in the same way as in the first or second embodiment described above. That is, in the manufacturing process of the display device 2, the self-luminous layer 156 on the outer edge side of the substrate 151 is removed to form the uneven portion. On the outer edge side of the substrate 151, the side surface of the insulating layer 152 is located on the active area AA side of the side surface of the substrate 151, and the upper surface of the substrate 151 (uneven portion) is in direct contact with the insulating layer 158 serving as the sealing layer. With this configuration, the display device 2 can reduce moisture entering from the outer edge side of the substrate 151.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments described above and the modifications thereof.

What is claimed is:

1. An electronic apparatus comprising:
a substrate;
a plurality of insulating films stacked on the substrate;
an organic semiconductor device provided on the insulating films in an active area of the substrate; and
a sealing film that covers the organic semiconductor device, wherein
the substrate, the insulating films, and the sealing film are stacked in a peripheral area outside the active area in the order as listed,
on an outer edge side of the substrate, side surfaces of the insulating layers are positioned on the active area side of a side surface of the substrate, and
in an area between a side surface of the substrate and side surfaces of the insulating layers on the outer edge side of the substrate, the sealing film is in direct contact with an upper surface of the substrate.

2. The electronic apparatus according to claim 1, wherein
in the area between the side surface of the substrate and the side surfaces of the insulating layers on the outer edge side of the substrate, a first uneven portion having a plurality of asperities is formed on the upper surface of the substrate, and
the sealing film covers the first uneven portion of the substrate.

3. The electronic apparatus according to claim 2, wherein
a height position of bottoms of the asperities in the first uneven portion of the substrate is lower than a height position of the upper surface of the substrate in an area overlapping the insulating films.

4. The electronic apparatus according to claim 1, wherein
on the outer edge side of the substrate, the sealing film covers the side surfaces of the insulating layers.

5. The electronic apparatus according to claim 1, comprising a groove that is formed so as to penetrate the insulating layers in a thickness direction and extends along the outer edge of the substrate in plan view in the peripheral area, wherein
the sealing film is in direct contact with the upper surface of the substrate at a bottom of the groove.

6. The electronic apparatus according to claim 5, wherein
a second uneven portion having a plurality of asperities is formed on the upper surface of the substrate at the bottom of the groove, and
the sealing film covers the second uneven portion at the bottom of the groove.

7. The electronic apparatus according to claim 5, wherein
the insulating films comprise a plurality of inorganic insulating films, an organic insulating film, and a barrier film,
the inorganic insulating films, the organic insulating film, and the barrier film are stacked on the substrate in the order as listed, and
the barrier film is provided so as to cover side surfaces of the inorganic insulating films and the organic insulating film in the groove and is not provided at the bottom of the groove.

8. The electronic apparatus according to claim 1, wherein
the organic semiconductor device is an organic optical sensor in which a lower electrode, a lower buffer layer, an active layer, an upper buffer layer, and an upper electrode are stacked in the active area of the substrate in the order as listed.

9. The electronic apparatus according to claim 1, wherein
the organic semiconductor device is an organic light-emitting element in which a lower electrode, a self-luminous layer, and an upper electrode are stacked in the active area of the substrate in the order as listed.
